(19) United States
(12) Patent Application Publication
(10) Pub. No.: US 2026/0164812 A1
(43) Pub. Date: Jun. 11, 2026

(54) MULTIPLE JUNCTION SOLAR CELL

(71) Applicant: TaiCrystal International Technologies Co., Ltd, Taoyuan City (TW)

(72) Inventors: Ray Young Lin, Taoyuan City (TW); Gui-Sheng Zeng, Taoyuan City (TW); Min Chao, Taoyuan City (TW); Wei-Cheng Liao, Taoyuan City (TW); Hui-Man Chung, Taoyuan City (TW)

(21) Appl. No.: 19/227,798

(22) Filed: Jun. 4, 2025

(30) Foreign Application Priority Data
Dec. 11, 2024 (TW) 113148256

(51) Int. Cl. H10F 10/142; H10F 77/30; H10F 77/42

(52) U.S. Cl. CPC H10F 10/142; H10F 77/315; H10F 77/42

(57) ABSTRACT

A multiple junction solar cell includes a first solar cell unit, a second solar cell unit, a third solar cell unit, a first anti-reflective coating, a second anti-reflective coating, an optical adhesive layer, a protective glass and a tantalum silicon oxide anti-reflective laminate. The multiple junction solar cell has a reflectance of less than 6.5% for light waves with a wavelength of 600 nm to 900 nm. The first solar cell unit, the second solar cell unit, and the third solar cell unit are connected in series, and absorb light waves with different wavelength within 600 nm to 900 nm, respectively, and convert the light waves absorbed into electrical energy. The tantalum silicon oxide anti-reflective laminate includes a first tantalum silicon oxide stacked layer and a second tantalum silicon oxide stacked layer, and has a thickness of less than 75 nm.

### CROSS-REFERENCE TO RELATED APPLICATION

This non-provisional application claims priority under 35 U.S.C. § 119(a) to Patent Application No. 113148256 filed in Taiwan, R.O.C. on Dec. 11, 2024, the entire contents of which are hereby incorporated by reference.

### BACKGROUND

### Technical Field

The present invention relates to the field of aerospace, and relates to a multiple junction solar cell suitable for space equipment.

### Related Art

With the emphasis on renewable energy and environmental sustainability, the development of green electricity, especially solar cells, has attracted attention. Nowadays, the solar cell has been recognized as a mainstream product of green electricity for its improved photoelectric conversion efficiency. Recently, with the development of low earth orbit (LEO) satellite communications, it is difficult to rely on other electrical energy in space. Therefore, the solar cell is also a key electrical energy element to provide LEO satellites or other space equipment.

Nowadays, due to the mainstream use of the solar cells on the earth's surface, the effect of atmosphere is often ignored when directly switched over for the design of solar cells used in the space equipment. Due to an atmospheric barrier on the earth's surface, short and medium wavelength solar light waves will be absorbed, refracted, or scattered by molecules, such as oxygen, nitrogen, and water molecules, in the atmosphere. The spectral energy and the number of photons on the earth's surface are lower than those in the space environment. In addition, because the atmosphere can also absorb the energy of solar flares, the energy of the solar flares in space is much greater than that on the earth's surface. Meanwhile, there are also electron streams, proton streams, or other high-energy particle streams in space. The energy of these high-energy rays may damage the structure of the solar cell.

In addition, in current designs of the solar cell used in space, considering that the intensity in short wavebands in space is much higher than that on the earth's surface, most of the designs only focus on reducing the reflectance of short wavelengths to improve the power generation efficiency. However, in a medium waveband in the wavelength of 600 nanometers to 900 nanometers, current solar cells have high reflectance (more than 10%). Even if the efficiency in the short waveband is good, the photoelectric performance of an entire solar cell in a state where the solar cells are connected in series is limited because the photocurrent generated at the medium waveband is the lowest.

### SUMMARY

A multiple junction solar cell is provided here, including a first solar cell unit, a second solar cell unit, a third solar cell unit, a first anti-reflective coating, a second anti-reflective coating, an optical adhesive layer, a protective glass and a tantalum silicon oxide anti-reflective laminate. The first solar cell unit is configured to absorb light waves with a wavelength of 660 nm or below and convert the light waves into electrical energy. The second solar cell unit is connected to a first lower surface of the first solar cell unit through a first tunneling junction, and is configured to absorb light waves with a wavelength of 600 nm to 900 nm and convert the light waves into electrical energy. The third solar cell unit is connected t a second lower surface of the second solar cell unit through a second tunneling junction, and is configured to absorb light waves with a wavelength of 900 nm or above and convert the light waves into electrical energy.

The first anti-reflective coating is on a first upper surface of the first solar cell unit, is made of titanium dioxide, and has a thickness of 45 nm to 75 nm. The second anti-reflective coating is on the first anti-reflective coating, is made of aluminum oxide, and has a thickness of 65 nm to 110 nm. The optical adhesive layer is on the second anti-reflective coating, and has a refractive index of 1.52 to 1.58. The protective glass is on the optical adhesive layer, and has a refractive index of 1.46 to 1.54 and less than that of the optical adhesive layer. The tantalum silicon oxide anti-reflective laminate includes at least a first tantalum silicon oxide stacked layer and a second tantalum silicon oxide stacked layer, the first tantalum silicon oxide stacked layer being on the protective glass, the second tantalum silicon oxide stacked layer being on the first tantalum silicon oxide stacked layer, and the tantalum silicon oxide anti-reflective laminate having a thickness of less than 750 nm; and the multiple junction solar cell has a reflectance of less than 6.5% for the light waves with the wavelength of 600 nm to 900 nm.

In some embodiments, the first tantalum silicon oxide stacked layer includes a first tantalum oxide layer and a first silicon dioxide layer. The first tantalum oxide layer has a thickness of 21 nm to 24 nm, and the first silicon dioxide layer is on the first tantalum oxide layer, and has a thickness of 9 nm to 12 nm.

More specifically, in some embodiments, the second tantalum silicon oxide stacked layer includes a second tantalum oxide layer and a second silicon dioxide layer, the second tantalum oxide layer has a thickness of 155 nm to 163 nm, and the second silicon dioxide layer is on the second tantalum oxide layer, and has a thickness of 226 nm to 234 nm.

Further, in some embodiments, the multiple junction solar cell further includes a third tantalum silicon oxide stacked layer, the third tantalum silicon oxide stacked layer including a third tantalum oxide layer and a third silicon dioxide layer, the third tantalum oxide layer having a thickness of 13 nm to 16 nm, and the third silicon dioxide layer being on the third tantalum oxide layer, and having a thickness of 45 nm to 48 nm.

In some embodiments, the first tantalum silicon oxide stacked layer includes a first silicon dioxide layer and a first tantalum oxide layer, the first tantalum oxide layer is on the first silicon dioxide layer, and the first silicon dioxide layer and the first tantalum oxide layer have thicknesses of 54 nm to 59 nm and 22 nm to 25 nm, respectively.

More specifically, in some embodiments, the second tantalum silicon oxide stacked layer includes a second silicon dioxide layer and a second tantalum oxide layer, the second tantalum oxide layer is on the second silicon dioxide layer, and the second silicon dioxide layer and the second tantalum oxide layer have thicknesses of 44 nm to 48 nm and 144 nm to 147 nm, respectively.

Further, in some embodiments, the multiple junction solar cell further includes a third tantalum silicon oxide stacked layer, the third tantalum silicon oxide stacked layer including a third silicon dioxide layer and a third tantalum oxide layer, the third tantalum oxide layer being on the third silicon dioxide layer, and the third silicon dioxide layer and the third tantalum oxide layer having thicknesses of 162 nm to 165 nm and 18 nm to 22 nm, respectively.

Furthermore, in some embodiments, the multiple junction solar cell further includes a top silicon dioxide layer, the top silicon dioxide layer being on a topmost layer of the tantalum silicon oxide anti-reflective laminate, and having a thickness of 74 nm to 80 nm.

In some embodiments, the optical adhesive layer has a thickness of 30 μm to 50 μm, and the protective glass has a thickness of 80 μm to 120 μm.

In some embodiments, the multiple junction solar cell has a reflectance of less than 5% for the light waves with the wavelength of 600 nm to 900 nm.

As described in the aforegoing embodiments, by installing the optical adhesive layer, the protective glass, and the tantalum silicon oxide anti-reflective laminate, direct bombardment by external high-energy electron streams and proton streams can be avoided, and damage to the structure of the solar cell is avoided. Meanwhile, the efficiency in the 600 nm to 900 nm wavebands is improved, and the photocurrent in a bottleneck section is boosted, thereby achieving the goal that the solar cell is more suitable for devices in outer space for its higher cell performance.

### BRIEF DESCRIPTION OF THE DRAWINGS

FIG. 1 is a schematic cross-sectional view of a multiple junction solar cell;

FIG. 2 is a schematic cross-sectional view of an embodiment of a multiple junction solar cell;

FIG. 3 is a schematic cross-sectional view of another embodiment of a solar cell; and

FIG. 4 is a reflectance-wavelength graph of a multiple junction solar cell and a comparative example.

### DETAILED DESCRIPTION

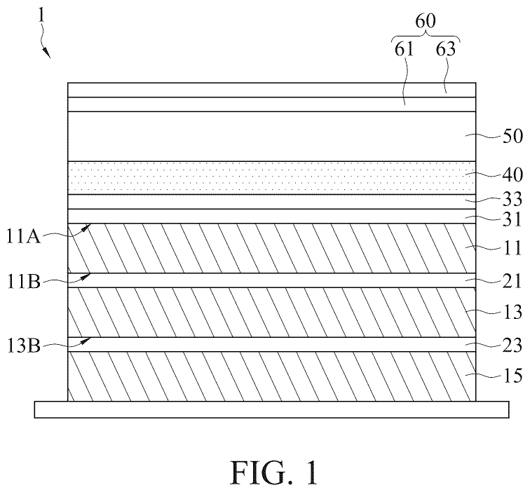

FIG. 1 is a schematic cross-sectional view of a multiple junction solar cell. As shown in FIG. 1, a multiple junction solar cell 1 includes a first solar cell unit 11, a second solar cell unit 13, a third solar cell unit 15, a first anti-reflective coating 31, a second anti-reflective coating 33, an optical adhesive layer 40, a protective glass 50, and a tantalum silicon oxide anti-reflective laminate 60. The first solar cell unit 11 may be made of GaInP, and is configured to absorb light waves with a wavelength of 660 nm or below and convert the light waves into electrical energy. In the first solar cell unit 11, the efficiency (quantum efficiency, EQE) of photons exciting electrons is about 0.8, that is, one photon may excite 0.8 electrons. Generally, most of the solar light waves with a wavelength above 660 nm will pass through the first solar cell unit 11 and enter the second solar cell unit 13.

The second solar cell unit 13 is connected to a first lower surface 11B of the first solar cell unit 11 through a first tunneling junction 21, may be made of InGaAs, and is configured to absorb light waves with a wavelength of 900 nm or below, especially light waves of 600 nm to 900 nm, and convert the light waves into electrical energy. The quantum efficiency in the second solar cell unit 13 is about 0.88. Solar light waves with a wavelength above 900 nm may pass through the second solar cell unit 13 and enter the third solar cell unit 15.

The third solar cell unit 15 is connected to a second lower surface 13B of the second solar cell unit 13 through a second tunneling junction 23, may be made of p type Ge, and is configured to absorb light waves with a wavelength of 900 nm or above, especially light waves of 900 nm to 1600 nm, and convert the light waves into electrical energy. The quantum efficiency in the third solar cell unit 15 is about 0.78 on average. The above materials and the number of the solar cells are for illustrative purposes only, and not intended to be limiting. Here is only an example of a series combination of the solar cells that may absorb light waves with short, medium, and long wavelengths.

Here, in the first solar cell unit 11, the second solar cell unit 13, and the third solar cell unit 15, due to the configuration of the wavelengths and the quantum efficiency, the overall current generation ratio is about 1.1:0.8:1. Since three solar cells are connected in series, the bottleneck of the overall solar current will fall on the waveband of the second solar cell unit 13. However, the above materials and wavebands are only examples, and not intended to be limiting. They only represent the absorption of solar light waves with short, medium, and long wavelengths via different configurations of semiconductor materials.

The first anti-reflective coating 31 is on a first upper surface 11A of the first solar cell unit 11, is made of titanium dioxide, and has a thickness of 45 nm to 75 nm. The second anti-reflective coating 33 is on the first anti-reflective coating 31, is made of aluminum oxide, and has a thickness of 65 nm to 110 nm. Through the first anti-reflective coating 31 and the second anti-reflective coating 33, reflected light produced by penetrating through the first solar cell unit 11, the second solar cell unit 13 and the third solar cell unit 15 may return to the first solar cell unit 11, the second solar cell unit 13 and the third solar cell unit 15 again for conversion, thereby improving the quantum efficiency.

The optical adhesive layer 40 is on the second anti-reflective coating 33, and has a refractive index of 1.52 to 1.58. The protective glass 50 is on the optical adhesive layer 40, and has a refractive index of 1.46 to 1.54 and less than that of the optical adhesive layer 40. The protective glass 50 is attached to the first solar cell unit 11 by the optical adhesive layer 40, thereby avoiding the direct shock of electron streams, proton streams or other high-energy particle streams on the first solar cell unit 11, the second solar cell unit 13 and the third solar cell unit 15. Further, partial refraction and scattering may also be provided to stabilize the solar light wave energy entering the first solar cell unit 11, the second solar cell unit 13, and the third solar cell unit 15. In some embodiments, the optical adhesive layer 40 has a thickness of 30 μm to 50 μm, and the protective glass 50 has a thickness of 80 μm to 120 μm.

The tantalum silicon oxide anti-reflective laminate 60 includes at least a first tantalum silicon oxide stacked layer 61 and a second tantalum silicon oxide stacked layer 63. The first tantalum silicon oxide stacked layer 61 is on the protective glass 50. The second tantalum silicon oxide stacked layer 63 is on the first tantalum silicon oxide stacked layer 61. The tantalum silicon oxide anti-reflective laminate 60 has a thickness of less than 750 nm, preferably 55 nm to 65 nm. The first tantalum silicon oxide stacked layer 61 and the second tantalum silicon oxide stacked layer 63 each include at least a stack of a tantalum oxide layer and a silicon oxide layer, and their interiors may be deployed according to actual specifications. Mainly through the stacking effect of multiple layers, reflected waves of the solar light waves with a wavelength of 600 nm to 900 nm are greatly reduced, so that the reflectance of the multiple junction solar cell 1 for the wavelength of 600 nm to 900 nm is less than 6.5%, and preferably, the reflectance of the solar cell 1 for the wavelength of 600 nm to 900 nm is less than 5%.

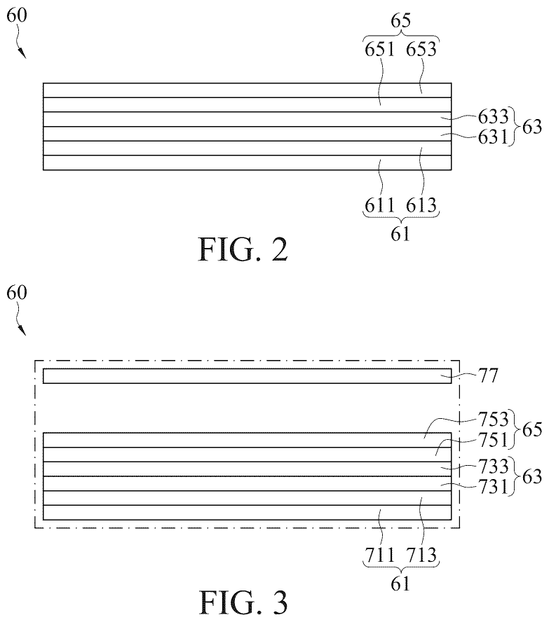

FIG. 2 is a schematic cross-sectional view of an embodiment of a solar cell. As shown in FIG. 2, the first tantalum silicon oxide stacked layer 61 includes a first tantalum oxide layer 611 and a first silicon dioxide layer 613. The first tantalum oxide layer 611 has a thickness of 21 nm to 24 nm. The first silicon dioxide layer 613 is on the first tantalum oxide layer 611, and has a thickness of 9 nm to 12 nm. In some embodiments, the second tantalum silicon oxide stacked layer 63 includes a second tantalum oxide layer 631 and a second silicon dioxide layer 633. The second tantalum oxide layer 631 has a thickness of 155 nm to 163 nm. The second silicon dioxide layer 633 is on the second tantalum oxide layer 631, and has a thickness of 226 nm to 234 nm.

Further, in some embodiments, the multiple junction solar cell 1 further includes a third tantalum silicon oxide stacked layer 65. The third tantalum silicon oxide stacked layer 65 includes a third tantalum oxide layer 651 and a third silicon dioxide layer 653. The third tantalum oxide layer 651 has a thickness of 13 nm to 16 nm. The third silicon dioxide layer 653 is on the third tantalum oxide layer 651, and has a thickness of 45 nm to 48 nm. Here, mainly by stacking the tantalum oxide layers, e.g., Ta₂O₅ and silicon dioxide (SiO₂) layers, the multilayer anti-reflection effect is achieved for the solar light waves with a wavelength of 600 nm to 900 nm, thereby reducing the reflectance for the wavelength of 600 nm to 900 nm.

FIG. 3 is a schematic cross-sectional view of another embodiment of a multiple junction solar cell. As shown in FIG. 3 and with reference to FIG. 2, unlike a first embodiment, the first tantalum silicon oxide stacked layer 61 includes a first silicon dioxide layer 711 and a first tantalum oxide layer 713. The first tantalum oxide layer 713 is on the first silicon dioxide layer 711. The first silicon dioxide layer 711 and the first tantalum oxide layer 713 have thicknesses of 54 nm to 59 nm and 22 nm to 25 nm, respectively. More specifically, in some embodiments, the second tantalum silicon oxide stacked layer 63 includes a second silicon dioxide layer 731 and a second tantalum oxide layer 733. The second tantalum oxide layer 733 is on the second silicon dioxide layer 731. The second silicon dioxide layer 731 and the second tantalum oxide layer 733 have thicknesses of 44 nm to 48 nm and 144 nm to 147 nm, respectively.

Further, in some embodiments, the solar cell 1 further includes a third tantalum silicon oxide stacked layer 65. The third tantalum silicon oxide stacked layer 65 includes a third silicon dioxide layer 751 and a third tantalum oxide layer 753. The third tantalum oxide layer 753 is on the third silicon dioxide layer 751. The third silicon dioxide layer 751 and the third tantalum oxide layer 753 have thicknesses of 162 nm to 165 nm and 18 nm to 22 nm, respectively.

Furthermore, in some embodiments, the multiple junction solar cell 1 further includes a top silicon dioxide layer 77. The top silicon dioxide layer 77 is on a topmost layer of the tantalum silicon oxide anti-reflective laminate 60, and has a thickness of 74 nm to 80 nm.

The stacked arrangement of the first tantalum silicon oxide stacked layer 61 and the second tantalum silicon oxide stacked layer 63 is different from that of the first embodiment. In a second embodiment, a similar effect is achieved on reducing the solar light waves with the wavelength of 600 nm to 900 nm, but the reflectance of the solar light waves with the wavelength 660 nm or below is increased. This design is based on the consideration that the current bottleneck of the cell still lies in the solar light waves with the wavelength of 600 nm to 900 nm, and even if the reflectance of the waveband in the low wavelength is increased, the effect of boosting the current of the cell can be achieved. Meanwhile, the case that the optical adhesive layer 40 yellows and its service life is shortened due to the fact that excessively high energy is absorbed is avoided.

However, the above is only an example, and not intended to be limiting. In fact, the number, arrangement, and thickness of the stacked layers in the tantalum silicon oxide anti-reflective laminate 60 can be adjusted according to actual specifications to achieve the best effect. It should be noted here that FIG. 1 to FIG. 3 are only for clear illustration and are not plotted according to the actual thickness ratio.

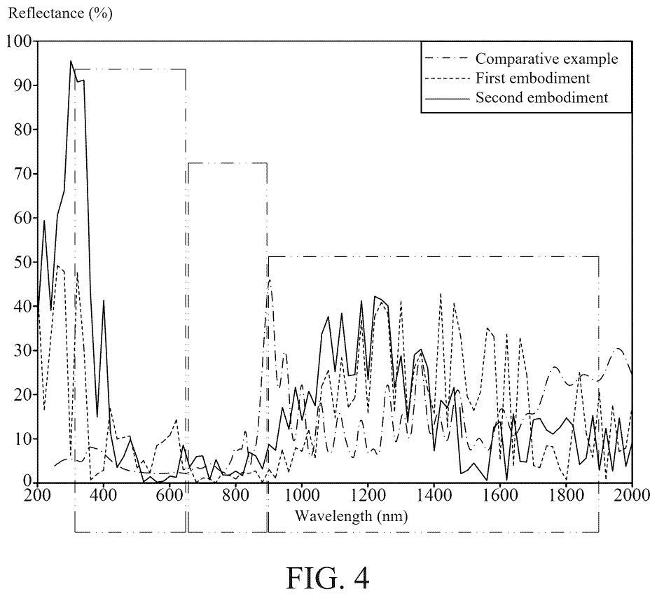

FIG. 4 is a reflectance-wavelength graph of a multiple junction solar cell and a comparative example. As shown in FIG. 4, FIG. 2 and FIG. 3 show the first embodiment and the second embodiment here, and a structure where the optical adhesive layer 40, the protective glass 50, and the tantalum silicon oxide anti-reflective laminate 60 are not installed is taken as a comparative example. It can be clearly found that the reflectance of the first embodiment and the second embodiment in the wavebands in the medium wavelength (wavelength of 600 nm to 900 nm) is reduced from 12% in the comparative example to 5% or below. Thus, even if the light waves with the wavelength of 600 nm to 900 nm are reflected, they can return to the second solar cell unit 13 again through the tantalum silicon oxide anti-reflective laminate 60, which boosts the photocurrent, so that the current in the bottleneck section of the multiple junction solar cell 1 is boosted.

In summary, by installing the optical adhesive layer 40, the protective glass 50, and the tantalum silicon oxide anti-reflective laminate 60, direct bombardment by external high-energy electron streams and proton streams can be avoided, and damage to the structure of the solar cell is avoided. Meanwhile, the efficiency in the 600 nm to 900 nm wavebands is improved, and the photocurrent in a bottleneck section is boosted, thereby achieving the goal that the solar cell is more suitable for devices in outer space for its higher cell performance.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A multiple junction solar cell, comprising:
a first solar cell unit, configured to absorb light waves with a wavelength of 660 nm or below and convert the light waves into electrical energy;
a second solar cell unit, connected to a first lower surface of the first solar cell unit through a first tunneling junction, and configured to absorb light waves with a wavelength of 600 nm to 900 nm and convert the light waves into electrical energy;
a third solar cell unit, connected to a second lower surface of the second solar cell unit through a second tunneling junction, and configured to absorb light waves with a wavelength of 900 nm or above and convert the light waves into electrical energy;
a first anti-reflective coating, on a first upper surface of the first solar cell unit, made of titanium dioxide, and having a thickness of 45 nm to 75 nm;
a second anti-reflective coating, on the first anti-reflective coating, made of aluminum oxide, and having a thickness of 65 nm to 110 nm;
an optical adhesive layer, on the second anti-reflective coating, and having a refractive index of 1.52 to 1.58;
a protective glass, on the optical adhesive layer, and having a refractive index of 1.46 to 1.54 and less than that of the optical adhesive layer; and
a tantalum silicon oxide anti-reflective laminate, comprising at least a first tantalum silicon oxide stacked layer and a second tantalum silicon oxide stacked layer, the first tantalum silicon oxide stacked layer being on the protective glass, the second tantalum silicon oxide stacked layer being on the first tantalum silicon oxide stacked layer, and the tantalum silicon oxide anti-reflective laminate having a thickness of less than 750 nm;
wherein the multiple junction solar cell has a reflectance of less than 6.5% for the light waves with the wavelength of 600 nm to 900 nm.

2. The multiple junction solar cell according to claim 1, wherein the first tantalum silicon oxide stacked layer comprises a first tantalum oxide layer and a first silicon dioxide layer, the first tantalum oxide layer has a thickness of 21 nm to 24 nm, and the first silicon dioxide layer is on the first tantalum oxide layer, and has a thickness of 9 nm to 12 nm.

3. The multiple junction solar cell according to claim 2, wherein the second tantalum silicon oxide stacked layer comprises a second tantalum oxide layer and a second silicon dioxide layer, the second tantalum oxide layer has a thickness of 155 nm to 163 nm, and the second silicon dioxide layer is on the second tantalum oxide layer, and has a thickness of 226 nm to 234 nm.

4. The multiple junction solar cell according to claim 3, further comprising a third tantalum silicon oxide stacked layer, the third tantalum silicon oxide stacked layer comprising a third tantalum oxide layer and a third silicon dioxide layer, the third tantalum oxide layer having a thickness of 13 nm to 16 nm, and the third silicon dioxide layer being on the third tantalum oxide layer, and having a thickness of 45 nm to 48 nm.

5. The multiple junction solar cell according to claim 1, wherein the first tantalum silicon oxide stacked layer comprises a first silicon dioxide layer and a first tantalum oxide layer, the first tantalum oxide layer is on the first silicon dioxide layer, and the first silicon dioxide layer and the first tantalum oxide layer have thicknesses of 54 nm to 59 nm and 22 nm to 25 nm, respectively.

6. The multiple junction solar cell according to claim 5, wherein the second tantalum silicon oxide stacked layer comprises a second silicon dioxide layer and a second tantalum oxide layer, the second tantalum oxide layer is on the second silicon dioxide layer, and the second silicon dioxide layer and the second tantalum oxide layer have thicknesses of 44 nm to 48 nm and 144 nm to 147 nm, respectively.

7. The multiple junction solar cell according to claim 6, further comprising a third tantalum silicon oxide stacked layer, the third tantalum silicon oxide stacked layer comprising a third silicon dioxide layer and a third tantalum oxide layer, the third tantalum oxide layer being on the third silicon dioxide layer, and the third silicon dioxide layer and the third tantalum oxide layer having thicknesses of 162 nm to 165 nm and 18 nm to 22 nm, respectively.

8. The multiple junction solar cell according to claim 7, further comprising a top silicon dioxide layer, the top silicon dioxide layer being on a topmost layer of the tantalum silicon oxide anti-reflective laminate, and having a thickness of 74 nm to 80 nm.

9. The multiple junction solar cell according to claim 1, wherein the optical adhesive layer has a thickness of 30 μm to 50 μm, and the protective glass has a thickness of 80 μm to 120 μm.

10. The multiple junction solar cell according to claim 1, wherein the multiple junction solar cell has a reflectance of less than 5% for the light waves with the wavelength of 600 nm to 900 nm.
